(19) United States
(12) Patent Application Publication
(10) Pub. No.: US 2014/0146918 A1
(43) Pub. Date: May 29, 2014

(54) Detection and Mitigation of an Abnormal Signal Condition Within a Power Amplifier (PA)

(71) Applicant: Broadcom Corporation, Irvine, CA (US)

(72) Inventors: Timothy Andrew RYAN, San Francisco, CA (US); Colin Douglas Nayler, Sunnyvale, CA (US)

(73) Assignee: Broadcom Corporation, Irvine, CA (US)

(21) Appl. No.: 14/075,265

(22) Filed: Nov. 8, 2013

Related U.S. Application Data
(60) Provisional application No. 61/730,460, filed on Nov. 27, 2012.

(51) Int. Cl. H04B 1/04; H03F 1/32

(52) U.S. Cl. CPC H04B 1/0475; H03F 1/3241
USPC 375/297

(57) ABSTRACT

A transmitter module of the present disclosure can detect for a presence of an abnormal signal condition, such as a frequency transient within a signal of the transmitter module which can damage the transmitter module, a signal within the transmitter module being at a sufficient power level which can damage the transmitter module, and/or a signal within the transmitter module being at a power level for a sufficient duration which can damage the transmitter module to provide some examples. Once the abnormal signal condition has been detected by the transmitter module, the transmitter module can mitigate effects of the abnormal signal condition to prevent damage within the transmitter module. The transmitter module can adjust an operating characteristic of a module within the transmitter module and/or a signal characteristic of a signal within the transmitter module to mitigate the effects of the abnormal signal condition.

### CROSS-REFERENCE TO RELATED APPLICATIONS

This patent application claims the benefit of U.S. Provisional Patent Application No. 61/730,460, filed Nov. 27, 2012, which is incorporated herein by reference in its entirety.

### BACKGROUND

1. Field of Disclosure

The present disclosure generally relates to a power amplifier, including detection and mitigation of an abnormal signal condition within the power amplifier.

2. Related Art

A consumer electronic device, such as an all-in-one computer, a tablet computer, a smartphone, a personal digital assistant (PDA), a satellite navigation device, a video gaming device, a kiosk system in retail and tourist settings, a point of sale system, an automatic teller machine (ATM) to provide some examples, includes a power amplifier (PA) to extend its range of communication. The PA can be used as a gain stage for amplifying analog signals for transmission. The PA can be damaged when presented with sudden high amplitude transients. For example, most conventional consumer electronic devices include digital pre-distortion (DPD) systems for pre-compensating for interference and/or distortion caused by the PA onto the analog signals for transmission. These DPD systems can sometimes provide the sudden high amplitude transients to the PA which can damage the PA.

### BRIEF DESCRIPTION OF THE DRAWINGS/FIGURES

The present disclosure is described with reference to the accompanying drawings. In the drawings, like reference numbers indicate identical or functionally similar elements. Additionally, the left most digit(s) of a reference number identifies the drawing in which the reference number first appears.

FIG. 1 illustrates a block diagram of a conventional transmitter module having a conventional power amplifier (PA);

FIG. 2 illustrates a block diagram of a first transmitter module having a conventional power amplifier (PA) according to an exemplary embodiment of the present disclosure;

FIG. 3 illustrates a block diagram of an exemplary protection module that can be implemented within the first transmitter module according to an exemplary embodiment of the present disclosure;

FIG. 4 illustrates a block diagram of a first exemplary transient detector that can be implemented within the protection module according to an exemplary embodiment of the present disclosure;

FIG. 5 illustrates a block diagram of a second transmitter module having a conventional power amplifier (PA) according to an exemplary embodiment of the present disclosure; and

FIG. 6 illustrates a block diagram of an exemplary protection module that can be implemented within the second transmitter module according to an exemplary embodiment of the present disclosure.

The present disclosure will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE DISCLOSURE

The following Detailed Description refers to accompanying drawings to illustrate exemplary embodiments consistent with the disclosure. References in the Detailed Description to “one exemplary embodiment,” “an exemplary embodiment,” “an example exemplary embodiment,” etc., indicate that the exemplary embodiment described can include a particular feature, structure, or characteristic, but every exemplary embodiment can not necessarily include the particular feature, structure, or characteristic. Moreover, such phrases are not necessarily referring to the same exemplary embodiment. Further, when a particular feature, structure, or characteristic is described in connection with an exemplary embodiment, it is within the knowledge of those skilled in the relevant art(s) to affect such feature, structure, or characteristic in connection with other exemplary embodiments whether or not explicitly described.

The exemplary embodiments described herein are provided for illustrative purposes, and are not limiting. Other exemplary embodiments are possible, and modifications can be made to the exemplary embodiments within the spirit and scope of the disclosure. Therefore, the Detailed Description is not meant to limit the disclosure. Rather, the scope of the disclosure is defined only in accordance with the following claims and their equivalents.

Embodiments of the disclosure can be implemented in hardware, firmware, software, or any combination thereof. Embodiments of the disclosure can also be implemented as instructions stored on a machine-readable medium, which can be read and executed by one or more processors. A machine-readable medium can include any mechanism for storing or transmitting information in a form readable by a machine (e.g., a computing device). For example, a machine-readable medium can include non-transitory machine-readable mediums such as read only memory (ROM); random access memory (RAM); magnetic disk storage media; optical storage media; flash memory devices; and others. As another example, the machine-readable medium can include transitory machine-readable medium such as electrical, optical, acoustical, or other forms of propagated signals (e.g., carrier waves, infrared signals, digital signals, etc.). Further, firmware, software, routines, instructions can be described herein as performing certain actions. However, it should be appreciated that such descriptions are merely for convenience and that such actions in fact result from computing devices, processors, controllers, or other devices executing the firmware, software, routines, instructions, etc.

The following Detailed Description of the exemplary embodiments will so fully reveal the general nature of the disclosure that others can, by applying knowledge of those skilled in relevant art(s), readily modify and/or adapt for various applications such exemplary embodiments, without undue experimentation, without departing from the spirit and scope of the disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein.

For purposes of this discussion, the term “module” shall be understood to include at least one of software, firmware, and hardware (such as one or more circuits, microchips, or devices, or any combination thereof), and any combination thereof. In addition, it will be understood that each module can include one, or more than one, component within an actual device, and each component that forms a part of the described module can function either cooperatively or independently of any other component forming a part of the module. Conversely, multiple modules described herein can represent a single component within an actual device. Further, components within a module can be in a single device or distributed among multiple devices in a wired or wireless manner.

A Conventional Transmitter

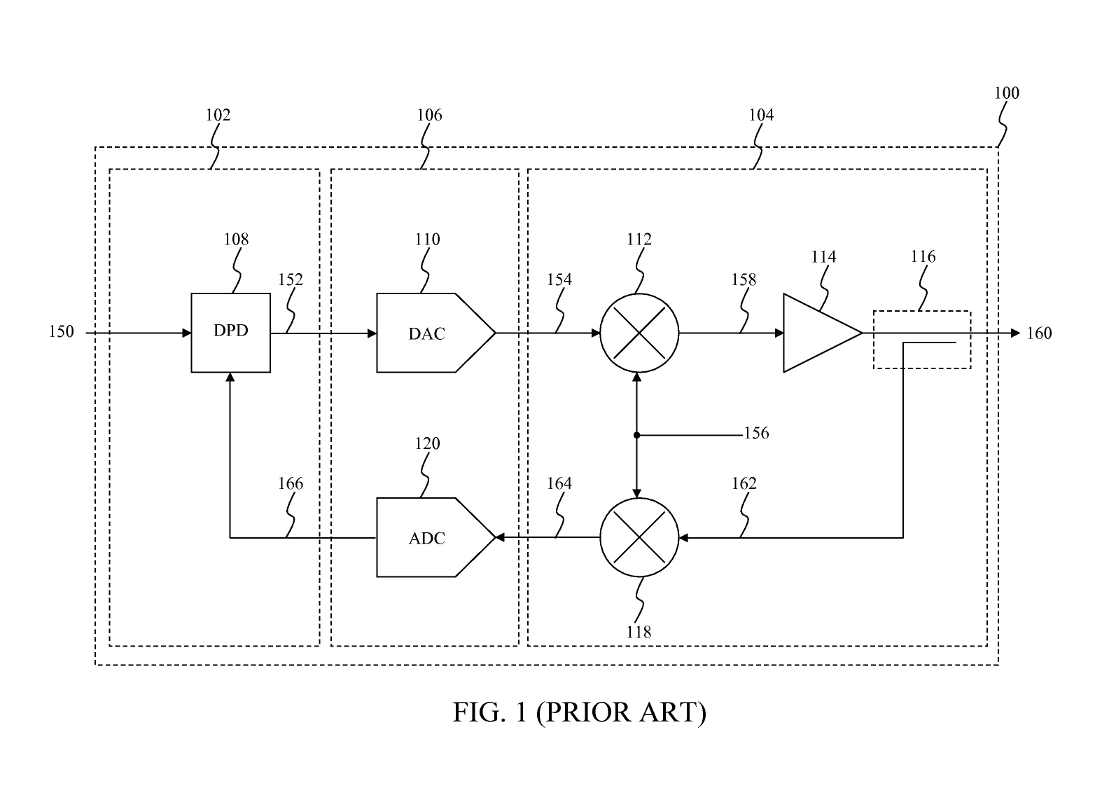

FIG. 1 illustrates a block diagram of a conventional transmitter module having a conventional power amplifier (PA). A conventional transmitter module 100 includes a digital processing module 102 for processing digital signals within the conventional transmitter module 100 and an analog processing module 104 for processing analog signals within the conventional transmitter module 100. The conventional transmitter module 100 additionally includes an interface module 106 to provide an interface between the digital processing module 102 and the analog processing module 104. Imperfections within the digital processing module 102, the analog processing module 104, and/or the interface module 106 can cause an abnormal signal condition with various signals within the conventional transmitter module 100. The abnormal signal condition can include abnormal frequency transients within the conventional transmitter module 100, continuous high power of the various signals within the conventional transmitter module 100, and/or saturation of the various signals within the conventional transmitter module 100 to provide some examples. The abnormal signal condition can cause the various signals within the conventional transmitter module 100 to have sufficient energy to damage the conventional transmitter module 100. For example, the abnormal signal condition can cause the various signals within the conventional transmitter module 100 to have sufficient energy to breakdown various semiconductor devices within the conventional transmitter module 100 which can cause permanent damage to the conventional transmitter module 100. Examples of breakdown may include punch-through breakdown, avalanche breakdown, and gate oxide breakdown to provide some examples.

The digital processing module 102 processes a digital input sequence 150 according to one or more digital processing functions to provide a pre-compensated output sequence 152. The digital processing module 102 can include a digital pre-distortion (DPD) module for pre-compensating for interference and/or distortion caused by a PA 114. The DPD module 108 estimates the interference and/or the distortion caused by the PA 114. Afterwards, the DPD module 108 determines a compensation waveform, based upon a digital feedback output sequence 166, which can be added to the digital input sequence 150 to compensate for the interference and/or the distortion. Thereafter, the DPD module 108 adjusts the digital input sequence 150 using the compensation waveform to pre-compensate for the interference and/or the distortion to provide a pre-compensated output sequence as the pre-compensated output sequence 152. This adjusting of the digital input sequence 150 with the compensation waveform can cause the abnormal signal condition within the conventional transmitter module 100.

The interface module 106 provides an interface between the digital processing module 102 and the analog processing module 104. The interface module 106 includes a digital-to-analog converter (DAC) 110 and an analog-to-digital converter (ADC) 120. The DAC 110 converts the pre-compensated output sequence 152 from a representation in a digital signal domain to a representation in an analog signal domain to provide an analog input signal 154. The ADC 120 converts an analog feedback input signal 164 from a representation in the analog signal domain to a representation in the digital signal domain to provide the digital feedback output sequence 166.

The analog processing module 104 processes the analog input signal 154 according to one or more analog processing functions to provide an analog output sequence 160 for transmission. The analog input signal 154 can cause the abnormal signal condition within the conventional transmitter module 100. The analog processing module 104 includes a first mixer 112, the PA 114, a directional coupler 116, and a second mixer 118. The first mixer 112 can frequency translate the analog input signal 154 using a local oscillator signal 156 to provide a translated analog signal 158. The first mixer 112 can frequency translate the analog input signal 154 to a radio frequency (RF) for transmission that will be apparent to those skilled in the relevant art(s) without departing from the spirit and scope of the present invention.

The PA 114 can amplify the translated analog signal 158 to provide the analog output sequence 160 for transmission. The digital input sequence 150 and/or the pre-compensated output sequence 152 can cause the abnormal signal condition within the conventional transmitter module 100. For example, the abnormal signal condition can occur when the digital input sequence 150 and/or the pre-compensated output sequence 152 include frequency transients which can damage the PA 114, are at a sufficient power level which can damage the PA 114, and/or are at a power level for a sufficient duration which can damage the PA 114. The abnormal signal condition can cause the translated analog signal 158 to have sufficient energy to damage the PA 114. For example, the PA 114 can include one or more semiconductor components. In this example, the abnormal signal condition can cause the translated analog signal 158 to have sufficient energy to breakdown the one or more semiconductor components which can cause permanent damage to the PA 114. Examples of breakdown can include punch-through breakdown, avalanche breakdown, and gate oxide breakdown to provide some examples. In this example, the abnormal signal condition can also cause the translated analog signal 158 to have sufficient energy, not to cause immediate damage to the one or more semiconductor components, but to decrease an operating lifetime of the one or more semiconductor components.

The directional coupler 116 is implemented with transmission lines that are set close enough together such that the analog output sequence 160 passing through one of the transmission lines is coupled to another one of the transmission lines to provide an analog feedback input sequence 162. The second mixer 118 can frequency translate the analog feedback input sequence 162 using the local oscillator signal 156 to provide the analog feedback input signal 164. The second mixer 118 can frequency translate the analog feedback input sequence 162 to baseband, near-baseband, or any suitable intermediate frequency (IF) that will be apparent to those skilled in the relevant art(s) without departing from the spirit and scope of the present invention.

Overview

A transmitter module of the present disclosure can detect for a presence of an abnormal signal condition, such as a frequency transient within a signal of the transmitter module which can damage the transmitter module, a signal within the transmitter module being at a sufficient power level which can damage the transmitter module, and/or a signal within the transmitter module being at a power level for a sufficient duration which can damage the transmitter module to provide some examples. Once the abnormal signal condition has been detected by the transmitter module, the transmitter module can mitigate effects of the abnormal signal condition to prevent damage within the transmitter module. The transmitter module can adjust an operating characteristic of a module within the transmitter module and/or a signal characteristic of a signal within the transmitter module to mitigate the effects of the abnormal signal condition.

Exemplary First Transmitter Module

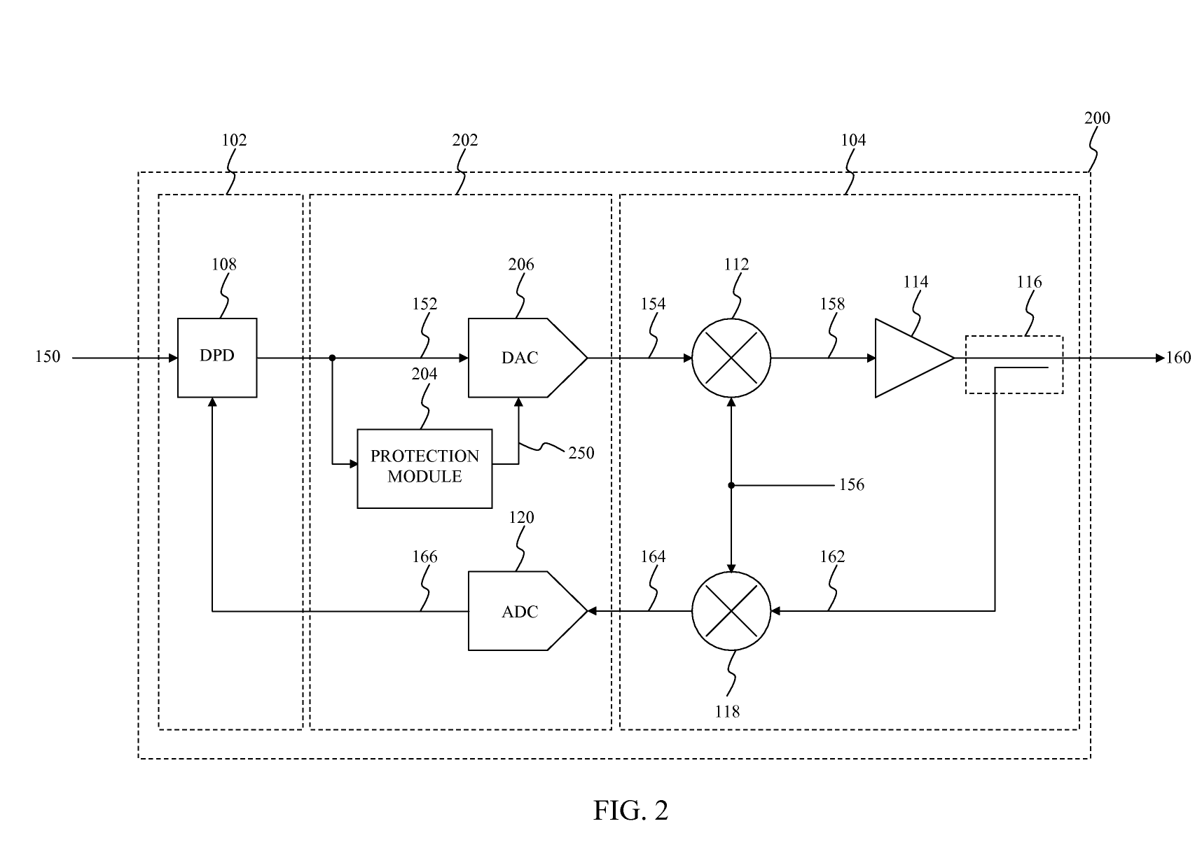

FIG. 2 illustrates a block diagram of a first transmitter module having a conventional power amplifier (PA) according to an exemplary embodiment of the present disclosure. A transmitter module 200 can detect for a presence of an abnormal signal condition, such as a frequency transient within a signal of the transmitter module 200 which can damage the transmitter module 200, a signal within the transmitter module 200 being at a sufficient power level which can damage the transmitter module 200, and/or a signal within the transmitter module 200 being at a power level for a sufficient duration which can damage the transmitter module 200 to provide some examples. Once the abnormal signal condition has been detected by the transmitter module 200, the transmitter module 200 can mitigate effects of the abnormal signal condition to prevent damage within the transmitter module 200. The transmitter module 200 shares many substantially similar features with the conventional transmitter module 100; therefore, only differences between the transmitter module 200 and conventional transmitter module 100 are to be discussed in further detail.

The transmitter module 200 includes an interface module 202 to provide an interface between the digital processing module 102 and the analog processing module 104. The interface module 202 includes a protection module 204 to detect for a presence of the abnormal signal condition within the pre-compensated output sequence 152. The abnormal signal condition can include a frequency transient within the pre-compensated output sequence 152 which can damage the transmitter module 200, the pre-compensated output sequence 152 being at a sufficient power level which can damage the transmitter module 200, and/or the pre-compensated output sequence 152 being at a power level for a sufficient duration which can damage the transmitter module 200 to provide some examples. In an exemplary embodiment, the protection module 204 can include multiple detectors whereby each detector is configured to detect one or more abnormal signal conditions from many possible abnormal signal conditions.

Upon detection of the abnormal signal condition within the pre-compensated output sequence 152, the protection module 204 can mitigate the effects of the abnormal signal condition to prevent damage within the transmitter module 200, and, in particular, to prevent damage to the PA 114. The protection module 204 can cause the DAC 206 to adjust an operating characteristic of the DAC 206 to adaptively control a magnitude of the analog input signal 154 to mitigate the effects of the abnormal signal condition. The protection module 204 can provide a DAC control signal 250 which causes the DAC 206 to adjust a gain, a dynamic range, attenuation, a sampling rate, a resolution, and/or any other suitable operating characteristic of the DAC 206 that will be apparent to those skilled in the relevant art(s) without departing from the spirit and scope of the present disclosure. In an exemplary embodiment, the protection module 204 can provide the DAC control signal 250 which effectively disables or mutes the DAC 206 from providing the analog input signal 154.

Preferably, the DAC control signal 250 can smoothly or softly adjust the operating characteristic of the DAC 206. For example, the DAC control signal 250 effectively adjusts the operating characteristic of the DAC 206 over multiple clock cycles to prevent the formation of other transients within the transmitter module 200 if the operating characteristic of the DAC 206 were to be abruptly adjusted. In an exemplary embodiment, the protection module 204 activates an abnormal signal condition timer upon detection of the abnormal signal condition to form a signal adjustment window. The abnormal signal condition timer can assume various timing values based upon the specific abnormal signal condition detected. Typically, these various timing values correspond to various durations in time when the various abnormal signal conditions are expected to subside after their detection. The DAC control signal 250 adjusts the operating characteristic of the DAC 206 over the signal adjustment window by adjusting the operating characteristic of the DAC 206 from a first state to a second state over multiple clock cycles within the signal adjustment window. After expiration of the abnormal signal condition timer, the DAC control signal 250 adjusts the operating characteristic of the DAC 206 over the signal adjustment window by adjusting the operating characteristic of the DAC 206 from the second state back to the first state the over multiple clock cycles. The protection module 204 can restart the abnormal signal condition timer anytime the abnormal signal condition is detected, even if the abnormal signal condition is detected during the signal adjustment window.

Exemplary Protection Module that can be Implemented within the First Transmitter Module

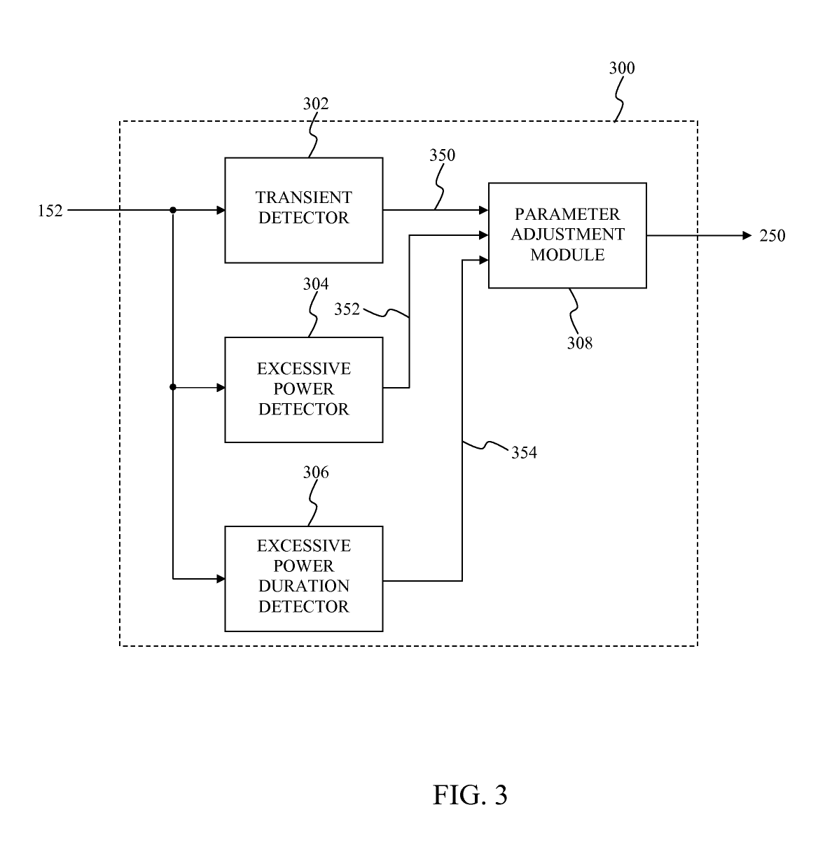

FIG. 3 illustrates a block diagram of an exemplary protection module that can be implemented within the first transmitter module according to an exemplary embodiment of the present disclosure. A protection module 300 can detect for a presence of the abnormal signal condition within one or more samples of the pre-compensated output sequence 152. Once the abnormal signal condition has been detected within the one or more samples, the protection module 300 can provide the DAC control signal 250 to adjust an operating characteristic of a DAC, such as the DAC 206 to provide an example 206, to mitigate the effects of the abnormal signal condition. The protection module 300 includes one or more of a transient detector 302, an excessive power detector 304, and an excessive power duration detector 306, and a parameter adjustment module 308. The protection module 300 can represent an exemplary embodiment of the protection module 204.

The transient detector 302 detects for a frequency transient within the one or more samples of the pre-compensated output sequence 152 which can damage a PA, such as the PA 114 to provide an example, within a transmitter module, such as the transmitter module 200 to provide an example. The frequency transient can include a magnitude transient and/or a phase transient. The transient detector 302 detects for a magnitude transient within the one or more samples of the pre-compensated output sequence 152 and/or a phase transient within the one or more samples of the pre-compensated output sequence 152. The transient detector 302 provides an abnormal signal condition indicator 350 to indicate a presence or an absence of the magnitude transient and/or the phase transient.

Exemplary Transient Detector Modules that can be Implemented within the Protection Module

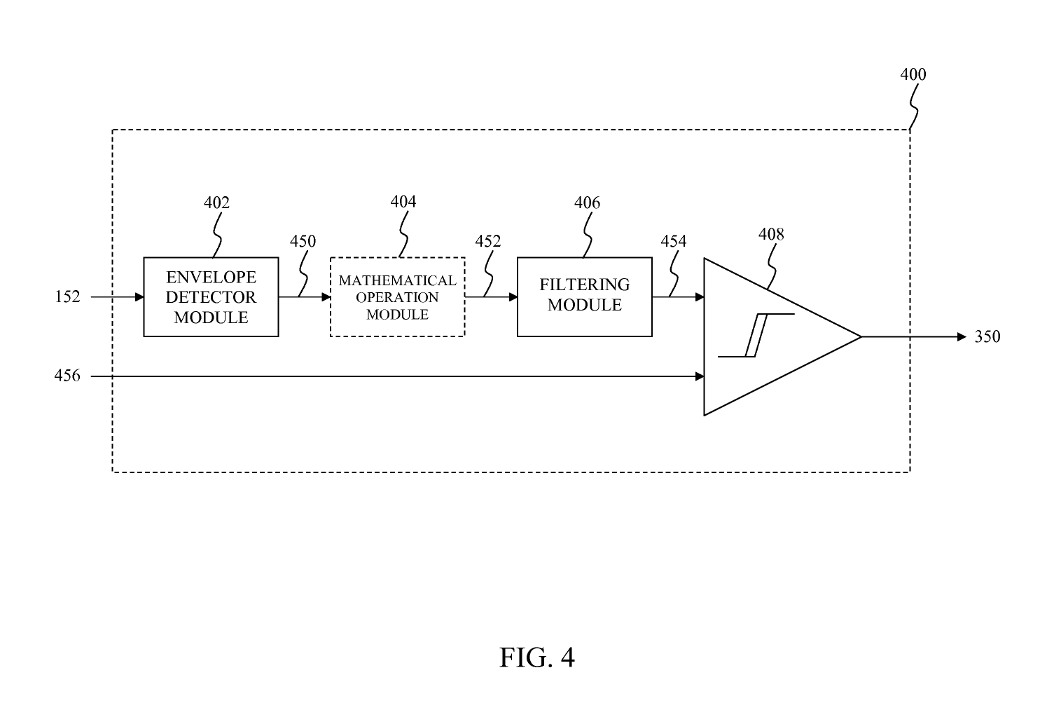

FIG. 4 illustrates a block diagram of a first exemplary transient detector that can be implemented within the protection module according to an exemplary embodiment of the present disclosure. A transient detector 400 detects for a magnitude transient within one or more samples of the pre-compensated output sequence 152 and provides the abnormal signal condition indicator 350 to indicate a presence or an absence of the magnitude transient. The transient detector 400 includes an envelope detector module 402, an optional mathematical operation module 404, a filtering module 406, and a comparator 408. The transient detector 400 can represent an exemplary embodiment of the transient detector 302.

The envelope detector module 402 determines an envelope of the one or more samples of the pre-compensated output sequence 152 to provide a pre-compensated envelope 450. The optional mathematical operation module 404 performs a mathematical operation, such as an absolute value to provide an example, on the pre-compensated envelope 450 to allow for easier detection of any magnitude transients within the one or more samples of the pre-compensated output sequence 152 to provide an absolute pre-compensated envelope 452.

The filtering module 406 filters the absolute pre-compensated envelope 452 to provide a filtered pre-compensated envelope 454. The filtering module 406 can be implemented using high pass filters for detecting high frequency transients within the absolute pre-compensated envelope 452. Typically, a signal bandwidth of the pre-compensated output sequence 152 is approximately 60% of a sampling rate of the DPD module 108. The high pass filters are configured to reject those portions of the absolute pre-compensated envelope 452 inside of the signal bandwidth of the pre-compensated output sequence 152 and to pass those portions of the absolute pre-compensated envelope 452 outside of the signal bandwidth of the pre-compensated output sequence 152.

The comparator 408 compares the filtered pre-compensated envelope 454 with a magnitude transient threshold to provide the abnormal signal condition indicator 350 which indicates the presence of the magnitude transient when the magnitude transient threshold is exceeded or the absence of the magnitude transient when the magnitude transient threshold is not exceeded.

Other configurations for the transient detector 302 are possible as will be apparent to those skilled in the relevant art(s) without departing from the spirit and scope of the present disclosure. In one such configuration and implementation, the transient detector 302 can include a first transient detector for detecting magnitude transients within one or more samples of pre-compensated output sequence 152 and a second transient detector for detecting phase transients within the one or more samples of pre-compensated output sequence 152.

The first transient detector determines a complex magnitude and power of the one or more samples of pre-compensated output sequence 152. Thereafter, a first order difference of the complex magnitude is computed and separated into a first, positive difference and a second, negative difference. The positive difference is weighted by a signal power of a trailing sample of the first order difference and the negative difference is weighted by a signal power of a leading sample of the first order difference. The weighted positive and negative differences are then applied to corresponding high pass filters. Next, absolute values of the filtered positive and negative differences are determined. Typically, the absolute values of the filtered positive and negative differences are proportional to a magnitude of the transients, if any, within the pre-compensated output sequence 152. The absolute values of the filtered positive and negative differences are then compared to a magnitude transient threshold which, when exceeded, causes the first transient detector to provide the abnormal signal condition indicator 350 which indicates the presence of the magnitude transient.

The second detector separates the one or more samples of the pre-compensated output sequence 152 into real and imaginary components. Thereafter, the second detector high pass filters the real and imaginary components of the pre-compensated output sequence 152. Next, the filtered real and imaginary components undergo a complex magnitude operation which produces one or more pulses when a phase transient is present within the pre-compensated output sequence 152. The one or more pulses are then compared to a phase transient threshold which, when exceeded, causes the second transient detector to provide the abnormal signal condition indicator 350 which indicates the presence of the phase transient.

Referring back to FIG. 3, the excessive power detector 304 detects whether the one or more samples of the pre-compensated output sequence 152 are at a sufficient power level which can damage the PA. The excessive power detector 304 compares a power level of the one or more samples of the pre-compensated output sequence 152 to an excessive power threshold. The excessive power detector 304 provides an abnormal signal condition indicator 352 to indicate a presence of the sufficient power level when the power level exceeds the excessive power threshold or to indicate an absence of the sufficient power level when the power level does not exceed the excessive power threshold.

The excessive power duration detector 306 detects whether a power level of one or more samples of the pre-compensated output sequence 152 is a power level for a sufficient duration which can damage the PA. The excessive power duration detector 306 compares a power level of the pre-compensated output sequence 152 to a power threshold. The power threshold can be less than the excessive power threshold as discussed above. When the power level of the pre-compensated output sequence 152 exceeds the power threshold, a counter is incremented. Otherwise, the counter is reset when the power level of the pre-compensated output sequence 152 does not exceed the power threshold. The excessive power duration detector 306 provides an abnormal signal condition indicator 354 to indicate a presence of the sufficient duration when a count of the counter reaches a predetermined count or to indicate an absence of the sufficient duration when the count of the counter does not reach the predetermined count.

The parameter adjustment module 308 can adjust an operating characteristic of the transmitter module to mitigate the effects of the abnormal signal condition. When one of the indicator 350, the indicator 352, and/or indicator 354 indicates the presence of the abnormal signal condition within the pre-compensated output sequence 152, the parameter adjustment module 308 activates an abnormal signal condition timer to form a signal adjustment window. The abnormal signal condition timer can assume various timing values based upon the specific abnormal signal condition detected. Typically, these various timing values correspond to various durations in time when the various abnormal signal conditions subside after their detection.

Thereafter, the parameter adjustment module 308 begins to adjust an operating characteristic of the DAC from a first state to a second state over multiple clock cycles within the signal adjustment window. The operating characteristic can include a gain, a dynamic range, attenuation, a sampling rate, a resolution, and/or any other suitable operating characteristic of the DAC that will be apparent to those skilled in the relevant art(s) without departing from the spirit and scope of the present disclosure. The parameter adjustment module 308 can restart the abnormal signal condition timer anytime the abnormal signal condition is detected, even if the abnormal signal condition is detected during the signal adjustment window.

After expiration of the abnormal signal condition timer, the parameter adjustment module 308 adjusts the operating characteristic of the DAC over the signal adjustment window by adjusting the operating characteristic of the DAC from the second state back to the first state over the multiple clock cycles. In an exemplary embodiment, the parameter adjustment module 308 adjusts the operating characteristic of the DAC from the second state back to the first state when the pre-compensated output sequence 152 is at a sufficiently low value such that any transients that may be produced from this adjustment are sufficiently minimized. The adjustment of the operating characteristic of the DAC from the first state to the second state and/or from the second state to the first state should be a smooth or soft transition to prevent formation of other transients if the operating characteristic of the DAC were to be abruptly adjusted.

Exemplary Second Transmitter Module

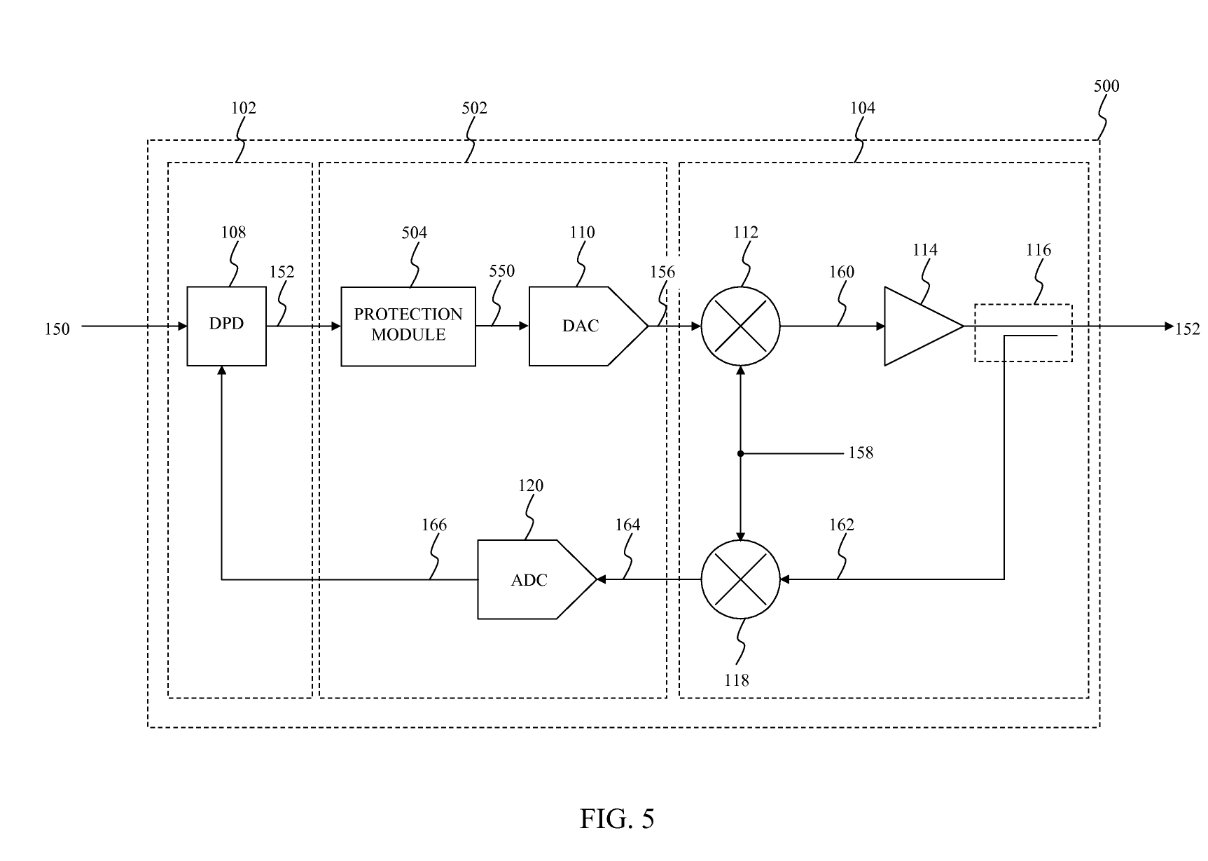

FIG. 5 illustrates a block diagram of a second transmitter module having a conventional power amplifier (PA) according to an exemplary embodiment of the present disclosure. A transmitter module 500 can detect for a presence of the abnormal signal condition in a substantially similar manner as the transmitter module 200. Once the abnormal signal condition has been detected by the transmitter module 500, the transmitter module 500 can mitigate effects of the abnormal signal condition to prevent damage within the transmitter module 500. The transmitter module 500 shares many substantially similar features with the conventional transmitter module 100 and the transmitter module 200; therefore, only differences between the transmitter module 500 and conventional transmitter module 100 and the transmitter module 200 are to be discussed in further detail.

The transmitter module 500 includes an interface module 502 to provide an interface between the digital processing module 102 and the analog processing module 104. The interface module 502 includes a protection module 504 to detect for a presence of the abnormal signal condition within the pre-compensated output sequence 152 in a substantially similar manner as the protection module 204. Upon detection of the abnormal signal condition within the pre-compensated output sequence 152, the protection module 504 can mitigate the effects of the abnormal signal condition to prevent damage within the transmitter module 500, and, in particular, to prevent damage to the PA 114. The protection module 504 can adjust a signal characteristic, such as a magnitude and/or a phase, of the pre-compensated output sequence 152 to mitigate the effects of the abnormal signal condition to provide an adjusted pre-compensated output sequence 550. Preferably, the protection module 504 can smoothly or softly adjust the signal characteristic of the pre-compensated output sequence 152 in a substantially similar manner as the protection module 204 adjusts the operating characteristic of the DAC 206.

Exemplary Protection Module that can be Implemented within the Second Transmitter Module

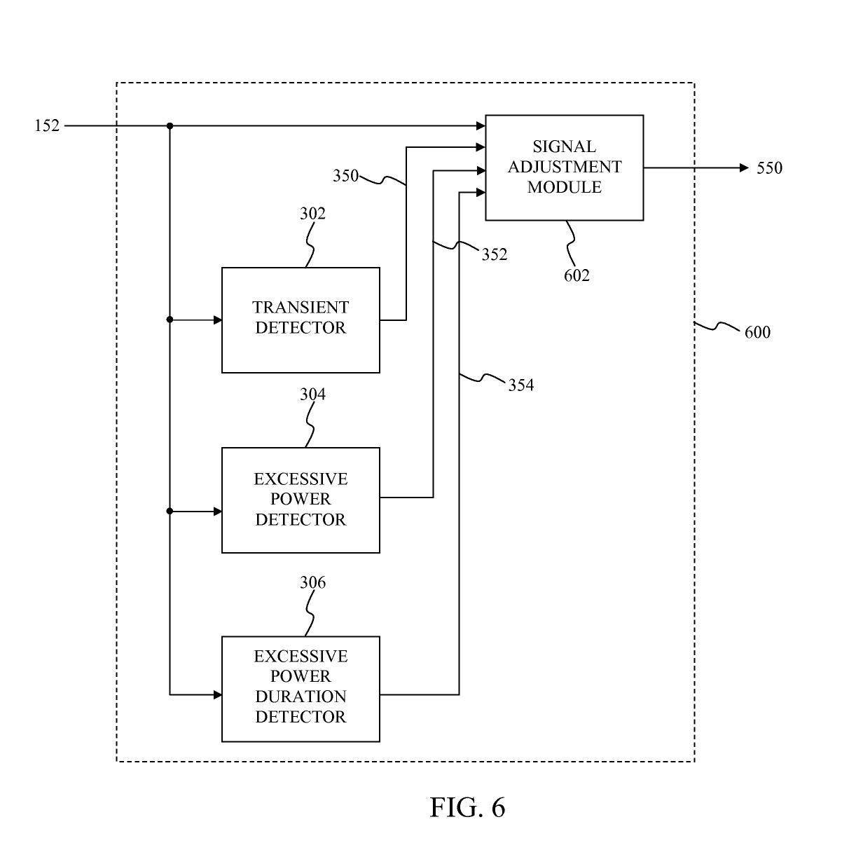

FIG. 6 illustrates a block diagram of an exemplary protection module that can be implemented within the second transmitter module according to an exemplary embodiment of the present disclosure. A protection module 600 can detect for a presence of the abnormal signal condition within one or more samples of the pre-compensated output sequence 152 in a substantially similar manner as the protection module 204 and/or the protection module 300. Once the abnormal signal condition has been detected within the one or more samples, the protection module 600 can adjust a signal characteristic, such as a magnitude and/or a phase, of the pre-compensated output sequence 152 to mitigate the effects of the abnormal signal condition. The protection module 600 includes one or more of the transient detector 302, the excessive power detector 304, and the excessive power duration detector 306, and a signal adjustment module 602. The protection module 600 can represent an exemplary embodiment of the protection module 504.

The signal adjustment module 602 can adjust the signal characteristic of the pre-compensated output sequence 152 to provide the adjusted pre-compensated output sequence 550. When one of the indicator 350, the indicator 352, and/or indicator 354 indicates the presence of the abnormal signal condition within the pre-compensated output sequence 152, the signal adjustment module 602 activates an abnormal signal condition timer to form a signal adjustment window in a substantially similar manner as the signal adjustment module 308.

Thereafter, the signal adjustment module 602 begins to adjust a signal characteristic of the pre-compensated output sequence 152 from a first state to a second state over multiple clock cycles within the signal adjustment window. The signal characteristic can include a magnitude, a phase, and/or any other suitable signal characteristic of the pre-compensated output sequence 152 that will be apparent to those skilled in the relevant art(s) without departing from the spirit and scope of the present disclosure. In an exemplary embodiment, the signal adjustment module 602 includes an adaptive filter whose impulse response can be adjusted to adjust the signal characteristic of the pre-compensated output sequence 152. The signal adjustment module 602 can restart the abnormal signal condition timer anytime the abnormal signal condition is detected, even if the abnormal signal condition is detected during the signal adjustment window.

After expiration of the abnormal signal condition timer, the signal adjustment module 602 adjusts the signal characteristic of the pre-compensated output sequence 152 over the signal adjustment window by adjusting the signal characteristic of the pre-compensated output sequence 152 from the second state back to the first state over the multiple clock cycles in a substantially similar manner as the signal adjustment module 308.

### CONCLUSION

It is to be appreciated that the Detailed Description section, and not the Abstract section, is intended to be used to interpret the claims. The Abstract section can set forth one or more, but not all exemplary embodiments, of the present disclosure, and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

It will be apparent to those skilled in the relevant art(s) that various changes in form and detail can be made therein without departing from the spirit and scope of the disclosure. Thus the present disclosure should not be limited by any of the above-described exemplary embodiments, but should be defined only in accordance with the following claims and their equivalents.

What is claimed is:

1. A transmitter module for mitigating effects of an abnormal signal condition, comprising:
a digital-to-analog converter (DAC) configured to convert a digital signal to an analog signal;
a power amplifier (PA) configured to provide an output signal for transmission based upon the analog signal; and
a protection module configured to detect for the abnormal signal condition within the digital signal, the abnormal signal condition being capable of causing the digital signal to have sufficient energy to damage the PA, and the protection module being further configured to cause the DAC to adjust an operating characteristic of the DAC upon detection of the abnormal signal condition to mitigate the effects of the abnormal signal condition.

2. The transmitter module of claim 1, wherein the abnormal signal condition comprises:
a frequency transient within the digital signal;
the digital signal being at a sufficient power level; or
the digital signal being at a power level for a sufficient duration.

3. The transmitter module of claim 1, wherein the abnormal signal condition is from a plurality of abnormal signal conditions, and wherein the protection module comprises:
a plurality of detectors, each detector from among the plurality of detectors being configured to detect a corresponding abnormal signal condition from among the plurality of abnormal signal conditions; and
a parameter adjustment module configured to activate an abnormal signal condition timer upon detection of one of the plurality of abnormal signal conditions to form a signal adjustment window, a duration of the abnormal signal condition timer being based upon the one of the plurality of abnormal signal conditions, and to adjust the operating characteristic of the DAC within the signal adjustment window.

4. The transmitter module of claim 3, wherein the parameter adjustment module is further configured to restart the abnormal signal condition timer upon detection of another one of the plurality of abnormal signal conditions from among the plurality of abnormal signal conditions.

5. The transmitter module of claim 1, wherein the protection module is configured cause the DAC to adjust the operating characteristic from a first state to a second state over multiple clock cycles.

6. The transmitter module of claim 1, further comprising:
a digital pre-distortion (DPD) module configured to determine a compensation waveform that can be added to its input sequence to compensate for interference or distortion caused by the PA to provide the digital signal.

7. The transmitter module of claim 1, wherein the operating characteristic of the DAC comprises:
a gain;
a dynamic range;
attenuation;
a sampling rate; or
a resolution.

8. The transmitter module of claim 1, wherein the protection module is configured cause the DAC to adjust the operating characteristic of the DAC to disable the DAC from providing the analog signal.

9. A transmitter module for mitigating effects of an abnormal signal condition, comprising:
a power amplifier (PA); and
a protection module configured to detect for the abnormal signal condition within a digital signal, the abnormal signal condition being capable of causing the digital signal to have sufficient energy to damage the PA, and the protection module being further configured to adjust a signal characteristic of the digital signal upon detection of the abnormal signal condition to mitigate the effects of the abnormal signal condition.

10. The transmitter module of claim 9, wherein the abnormal signal condition comprises:
a frequency transient within the digital signal;
the digital signal being at a sufficient power level; or
the digital signal being at a power level for a sufficient duration.

11. The transmitter module of claim 9, wherein the abnormal signal condition is from a plurality of abnormal signal conditions, and wherein the protection module comprises:
a plurality of detectors, each detector from among the plurality of detectors being configured to detect a corresponding abnormal signal condition from among the plurality of abnormal signal conditions; and
a parameter adjustment module configured to activate an abnormal signal condition timer upon detection of one of the plurality of abnormal signal conditions to form a signal adjustment window, a duration of the abnormal signal condition timer being based upon the one of the plurality of abnormal signal conditions, and to adjust the signal characteristic of the digital signal within the signal adjustment window.

12. The transmitter module of claim 11, wherein the parameter adjustment module is further configured to restart the abnormal signal condition timer upon detection of another one of the plurality of abnormal signal conditions from among the plurality of abnormal signal conditions.

13. The transmitter module of claim 9, wherein the protection module is configured cause the DAC to adjust the signal characteristic from a first state to a second state over multiple clock cycles.

14. The transmitter module of claim 9, further comprising:
a digital pre-distortion (DPD) module configured to determine a compensation waveform that can be added to its input sequence to compensate for interference or distortion caused by the PA to provide the digital signal.

15. The transmitter module of claim 9, wherein the signal characteristic of the digital signal comprises:
a magnitude; or
a phase.

16. A transmitter module for mitigating effects of an abnormal signal condition, comprising:
a digital processing module configured to process a digital input signal to provide a digital output signal;
an analog processing module configured to process an analog input signal to provide an analog output signal; and
an interface module configured:
to convert the digital output signal from a representation in a digital signal domain to a representation in an analog signal domain to provide the analog input signal,
to detect for the abnormal signal condition within the interface module, the abnormal signal condition being capable of causing the digital signal to have sufficient energy to damage the analog processing module, and
to adjust a characteristic upon detection of the abnormal signal condition so as to mitigate the effects of the abnormal signal condition.

17. The transmitter module of claim 16, wherein the interface module comprises:
a digital-to-analog converter (DAC) configured to convert the digital output signal to the analog input signal, and
wherein the characteristic is an operating characteristic of the DAC.

18. The transmitter module of claim 16, wherein the characteristic is a signal characteristic of the digital output signal.

19. The transmitter module of claim 16, wherein the abnormal signal condition is from a plurality of abnormal signal conditions, and wherein the interface module comprises:
a plurality of detectors, each detector from among the plurality of detectors being configured to detect a possible abnormal signal condition from among the plurality of abnormal signal conditions; and
a parameter adjustment module configured to activate an abnormal signal condition timer upon detection of the abnormal signal condition to form a signal adjustment window, a duration of the abnormal signal condition timer being based upon the possible abnormal signal condition detected by one of the plurality of detectors, and to adjust the characteristic within the signal adjustment window.

20. The transmitter module of claim 19, wherein the parameter adjustment module is further configured to restart the abnormal signal condition timer upon detection of another abnormal signal condition from among the plurality of abnormal signal conditions.
